(19) United States
(12) Patent Application Publication
(10) Pub. No.: US 2019/0037682 A1
(43) Pub. Date: Jan. 31, 2019

(54) COF FLEXIBLE CIRCUIT BOARD AND TOUCH DISPLAY PANEL

(71) Applicant: WUHAN CHINA STAR OPTOELECTRONICS TECHNOLOGY CO., LTD., Wuhan, Hubei (CN)

(72) Inventors: Yu-Cheng Tsai, Wuhan, Hubei (CN); Zhou Zhang, Wuhan, Hubei (CN); Pan Xu, Wuhan, Hubei (CN); Changwen Ma, Wuhan, Hubei (CN); Yaling Zhou, Wuhan, Hubei (CN)

(21) Appl. No.: 15/576,636

(22) PCT Filed: Aug. 18, 2017
(86) PCT No.: PCT/CN2017/098131

§ 371 Date: Nov. 22, 2017

(30) Foreign Application Priority Data
Jul. 28, 2017 (CN) 201710630856.0

(51) Int. Cl. H05K 1/02; H05K 1/18; H05K 1/14; G06F 3/041; G06K 9/00

(52) U.S. Cl. CPC H05K 1/028; H05K 1/181; H05K 1/144; G06F 3/0416; G06F 3/0412; G06F 2203/04102; H05K 2201/055; H05K 2201/10128; H05K 2201/041; H05K 2201/10151; G06K 9/0002

(57) ABSTRACT

The present disclosure provides a COF flexible circuit board including a flexible package substrate and a control chip packaged on the flexible package substrate, the flexible package substrate is provided with an input terminal wiring and an output terminal wiring connected with the control chip, and the control chip includes a display driver for controlling a display panel, a touch controller for implementing a touch control function, and a fingerprint identification controller for implementing fingerprint identification that are packaged together. The present disclosure also provides a touch display panel including a display panel and a touch screen, and also including the COF flexible circuit board, the COF flexible circuit board being connected with the display panel and the touch screen. Compared with the prior art, the present disclosure saves material costs and wiring space by integrating and packaging display, touch control and fingerprint identification into one control chip.

### TECHNICAL FIELD

The present disclosure relates to a display panel technology, and particularly, to a COF flexible circuit board and a touch display panel.

### BACKGROUND ART

At present, touch control and display functions of a smart phone are independently controlled by two chips, i.e., a touch chip and a display drive chip; later, in order to save materials, a Touch control and Display Driver Integration (TDDI) Integrated Circuit (IC) appears on a Chip on Film (COF) flexible circuit board of a touch display panel for supporting products. The most prominent feature of the TDDI IC is to integrate the touch control chip and the display chip into a single chip. As a fingerprint identification module group has become a standard configuration in smart products such as a smart phone, how to further save the material costs and wiring space of smart products has become one direction for current research in the industry.

### SUMMARY

To overcome inadequacy in the prior art, the present disclosure provides a COF flexible circuit board and a touch display panel to integrate a fingerprint identification function into the COF flexible circuit board, thereby saving space and space for wiring, and saving costs.

The present disclosure provides a COF flexible circuit board including a flexible package substrate and a control chip packaged on the flexible package substrate, the flexible package substrate is provided with an input terminal wiring and an output terminal wiring connected with the control chip, and the control chip includes a display driver for controlling a display panel, a touch controller for implementing a touch control function, and a fingerprint identification controller for implementing fingerprint identification that are packaged together.

Further, the control chip also includes a package layer packaging the display driver, the touch controller, and the fingerprint identification controller.

Further, the control chip is provided with a fingerprint sensor connected with the fingerprint identification controller, a holder for fixing the fingerprint sensor is provided on a surface of the package layer, the fingerprint sensor is fixed in the holder, and a fingerprint identification region is formed on a surface of the package layer.

Further, the control chip is provided with a fingerprint sensor connected with the fingerprint identification controller, the fingerprint sensor is embedded into the package layer, and a fingerprint identification region is formed on a surface of the package layer.

Further, the package layer includes a circuit package region in which the display driver, the touch controller and the fingerprint identification controller are packaged, and an inlay region in which the fingerprint sensor is embedded.

Further, the flexible package substrate includes a non-bending region, a bending region provided at one side of the non-bending region, and a folding region provided at one side of the bending region away from the non-bending region.

Further, the control chip is provided in the non-bending region.

Further, the control chip is provided in the bending region.

Further, the control chip is provided in the folding region.

The present disclosure also provides a touch display panel including a display panel and a touch screen, and also including the COF flexible circuit board, the flexible package substrate being connected with the display panel and the touch screen.

Compared with the prior art, the present disclosure saves material costs and wiring space by integrating and packaging display, touch control and fingerprint identification into one control chip.

### BRIEF DESCRIPTION OF THE DRAWINGS

FIG. 1 is a structural schematic diagram of Embodiment 1 of the present disclosure;

FIG. 2 is a structural schematic diagram of Embodiment 2 of the present disclosure;

FIG. 3 is a schematic diagram of a first manner that the present disclosure is connected with a touch display screen;

FIG. 4 is a schematic diagram of a second manner that the present disclosure is connected with a touch display screen; and

FIG. 5 is a schematic diagram of a third manner that the present disclosure is connected with a touch display screen.

### DETAILED DESCRIPTION OF EXEMPLARY EMBODIMENTS

Below, the present disclosure is further explained in detail in conjunction with the figures and embodiments.

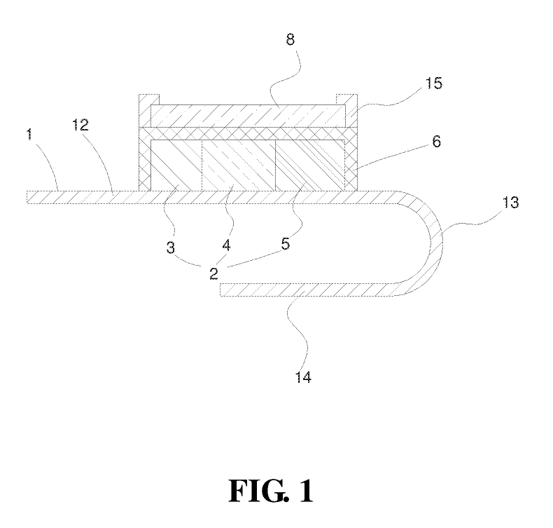

As illustrated in FIG. 1, the COF flexible circuit board of the present disclosure includes a flexible package substrate 1 and a control chip 2 packaged on the flexible package substrate 1, the flexible package substrate 1 is provided with an input terminal wiring and an output terminal wiring connected with the control chip 2, and the control chip 2 includes a display driver 3 for controlling a display panel, a touch controller 4 for implementing a touch control function, and a fingerprint identification controller 5 for implementing fingerprint identification that are packaged together through a package layer 6. The present disclosure enables the COF flexible circuit board to be integrated into a corresponding fingerprint identification function by integrating the display driver 3, the touch controller 4 and the fingerprint identification controller 5 into one chip, thereby saving materials, saving costs and improving cost performance.

An input terminal lead (ILB) and an output terminal lead (OLB) are provided at both ends of the COF flexible circuit board to thereby obtaining touch control signal and fingerprint signal and sending to a control panel of the smart product for processing.

As illustrated in FIG. 1, the COF flexible circuit board in Embodiment 1 includes a flexible package substrate 1 and a control chip 2 packaged on the flexible package substrate 1, the flexible package substrate 1 is provided with an input terminal wiring and an output terminal wiring connected with the control chip 2, the control chip 2 includes a display driver 3 for controlling a display panel, a touch controller 4 for implementing a touch control function, and a fingerprint identification controller 5 for implementing fingerprint identification that are packaged together through a package layer 6, a fingerprint sensor 8 is provided on a surface of the package layer 6, and the fingerprint sensor 8 is provided on the surface of the package layer 6 through a holder 15 and connected with the fingerprint identification controller 5 to thereby form a fingerprint identification region on the package layer 6. Here, it should be noted that the holder 15 may be fixed with the the package layer 6 through a manner of sticking, which will not be defined specifically herein.

In Embodiment 1, a cover plate may be further provided on the fingerprint sensor 8. Of course, the cover plate may also be directly replaced by a cover plate for the touch display panel to further save material costs.

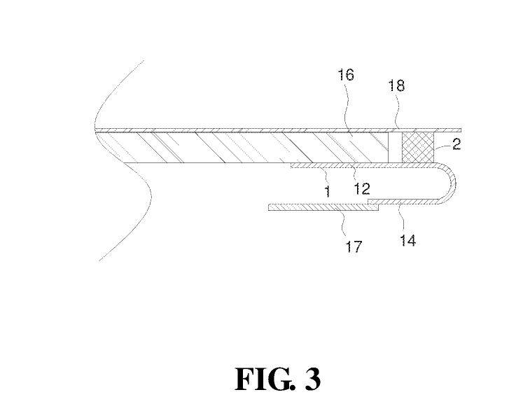

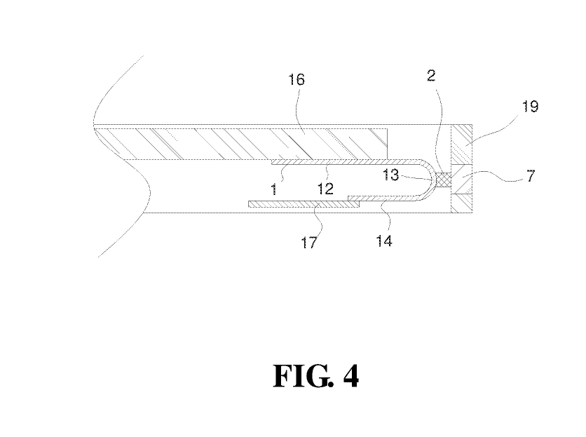

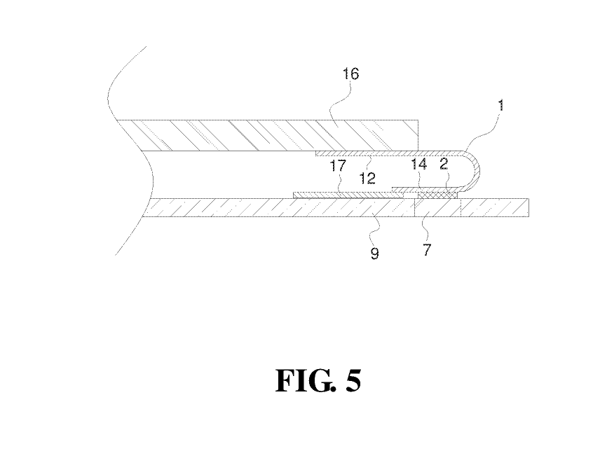

In Embodiment 1, the flexible package substrate 1 is provided with a non-bending region 12, a bending region 13 and a folding region 14, wherein the bending region 13 is used for bending the flexible package substrate 1, and the folding region 14 is located at a rear face (a non-viewing face) of the touch display panel or a rear face (a side opposite to the touch display panel) of the smart product, thereby implementing an effect of a narrow bezel. There are three conditions for disposing positions of the control chip 2 in the above Embodiment 1, the first is to provide the control chip 2 in the non-bending region 12 (as illustrated in FIG. 3), the second is to provide the control chip 2 in the bending region 13 (as illustrated in FIG. 4), and the third is to provide the control chip 2 in the folding region 14 (as illustrated in FIG. 5); the above three manners may satisfy demands for conventional disposing positions of fingerprint identification of smart products.

The non-bending region 12 and the folding region 14 are both provided with the input terminal lead (ILB) and the output terminal lead (OLB).

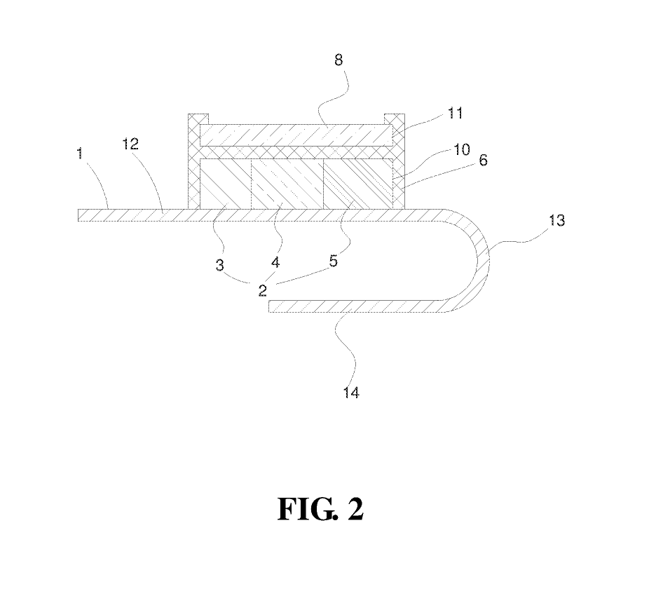

As illustrated in FIG. 2, the COF flexible circuit board in Embodiment 2 includes a flexible package substrate 1 and a control chip 2 packaged on the flexible package substrate 1, the flexible package substrate 1 is provided with an input terminal wiring and an output terminal wiring connected with the control chip 2, the control chip 2 includes a display driver 3 for controlling a display panel, a touch controller 4 for implementing a touch control function, and a fingerprint identification controller 5 for implementing fingerprint identification that are packaged together through a package layer 6, and a fingerprint sensor 8 is embedded in the surface of the package layer 6 and connected with the fingerprint identification controller 5 to thereby form a fingerprint identification region on the package layer 6.

As illustrated in FIG. 2, the package layer 6 includes a circuit package region 10 in which the display driver 3, the touch controller 4 and the fingerprint identification controller 5 are packaged, and an inlay region 11 in which the fingerprint sensor 8 is embedded, to thereby further saving material costs.

In Embodiment 2, a cover plate may be further provided on the fingerprint sensor 8. Of course, the cover plate may also be directly replaced by a cover plate for the touch display panel, which further saves material costs.

In Embodiment 2, the flexible package substrate 1 is provided with a non-bending region 12, a bending region 13 and a folding region 14, wherein the bending region 13 is used for bending the flexible package substrate 1, and the folding region 14 is located at a rear face (a non-viewing face) of the touch display panel or a rear face (a side opposite to the touch display panel) of the smart product, thereby implementing an effect of a narrow bezel. There are three conditions for disposing positions of the control chip 2 in the above Embodiment 2, the first is to provide the control chip 2 in the non-bending region 12 (as illustrated in FIG. 3), the second is to provide the control chip 2 in the bending region 13 (as illustrated in FIG. 4), and the third is to provide the control chip 2 in the folding region 14 (as illustrated in FIG. 5); the above three manners may satisfy demands for conventional disposing positions of fingerprint identification of smart products.

The non-bending region 12 and the folding region 14 are both provided with the input terminal lead (ILB) and the output terminal lead (OLB).

In the above two embodiments, a surface area of the package layer 6 is adjusted correspondingly according to an area of the fingerprint identification region, that is, if the fingerprint identification region is provided at a cover plate side and a rear cover side of the smart product, the area of the fingerprint identification region is larger than that thereof when it is provided at the bezel of the smart product, which will not be specifically defined here.

FIG. 3 is a structural schematic diagram of the first kind of touch display panel of the present disclosure, the touch display panel includes a display panel and a touch screen 16, and further includes the above described COF flexible circuit board; the flexible package substrate 1 is connected with the display panel and the touch screen 16 through the input terminal lead (ILB) and the output terminal lead (OLB) provided in the non-bending region 12; here, the control chip 2 is provided in the non-bending region 12, when the second kind of touch display panel is applied to the smart product, the fingerprint identification region and the touch display panel are provided at the same side, i.e., at the front, thereby implementing integration of the appearance by covering a glass cover plate 18 on the touch display panel and the fingerprint identification region, and the flexible package substrate 1 is connected with a printed circuit board (FPCA) 17 of the smart product through the input terminal lead (ILB) and the output terminal lead (OLB) provided in the folding region 14 to implement transmission of signals with a main board of the smart product.

FIG. 4 is a structural schematic diagram of the second kind of touch display panel of the present disclosure, the touch display panel includes a display panel and a touch screen 16, and further includes the above described COF flexible circuit board; the flexible package substrate 1 is connected with the display panel and the touch screen 16 through the input terminal lead (ILB) and the output terminal lead (OLB) provided in the non-bending region 12; here, the control chip 2 is provided in the bending region 13, when the second kind of touch display panel is applied to the smart product, the fingerprint identification region is provided at a bezel 19 of the smart product, a fingerprint cover plate 7 is provided on a position of the bezel 19 corresponding to a position of the fingerprint identification region, and the flexible package substrate 1 is connected with the printed circuit board (FPCA) 17 of the smart product through the input terminal lead (ILB) and the output terminal lead (OLB) provided in the folding region 14 to implement transmission of signals with a main board of the smart product.

FIG. 5 is a structural schematic diagram of the third kind of touch display panel of the present disclosure, the touch display panel includes a display panel and a touch screen, and further includes the above described COF flexible circuit board; the flexible package substrate 1 is connected with the display panel and the touch screen 16 through the input terminal lead (ILB) and the output terminal lead (OLB) provided in the non-bending region 12; here, the control chip 2 is provided in the folding region 14, when the third kind of touch display panel is applied to the smart product, the fingerprint identification region and the touch display panel are provided at an opposite side, i.e., at the back, thereby implementing the function of the fingerprint identification by providing a fingerprint cover plate 7 at a rear cover 9 of the smart product located at a position of the fingerprint identification region, and the flexible package substrate 1 is connected with the printed circuit board (FPCA) 17 of the smart product through the input terminal lead (ILB) and the output terminal lead (OLB) provided in the folding region 14 to implement transmission of signals with a main board of the smart product.

Through the above three disposing manners, a narrow bezel of the smart product is implemented, and a proportion of the display screen of the product is increased.

Although the present disclosure has been illustrated and described with reference to specific embodiments, those skilled in the art will understand that various changes in forms and details may be made therein without departing from the spirit and scope of the present disclosure as defined by the claims and their equivalents.

What is claimed is:

1. A chip on film (COF) flexible circuit board, comprising a flexible package substrate and a control chip packaged on the flexible package substrate, wherein the flexible package substrate is provided with an input terminal wiring and an output terminal wiring connected with the control chip, and the control chip comprises a display driver for controlling a display panel, a touch controller for implementing a touch control function, and a fingerprint identification controller for implementing fingerprint identification that are packaged together.

2. The COF flexible circuit board of claim 1, wherein the control chip further comprises a package layer packaging the display driver, the touch controller, and the fingerprint identification controller.

3. The COF flexible circuit board of claim 2, wherein the control chip is provided with a fingerprint sensor connected with the fingerprint identification controller, a holder for fixing the fingerprint sensor is provided on a surface of the package layer, the fingerprint sensor is fixed in the holder, and a fingerprint identification region is formed on a surface of the package layer.

4. The COF flexible circuit board of claim 2, wherein the control chip is provided with a fingerprint sensor connected with the fingerprint identification controller, the fingerprint sensor is embedded into the package layer, and a fingerprint identification region is formed on a surface of the package layer.

5. The COF flexible circuit board of claim 4, wherein the package layer comprises a circuit package region in which the display driver, the touch controller and the fingerprint identification controller are packaged, and an inlay region in which the fingerprint sensor is embedded.

6. The COF flexible circuit board of claim 1, wherein the flexible package substrate comprises a non-bending region, a bending region provided at one side of the non-bending region, and a folding region provided at one side of the bending region away from the non-bending region.

7. The COF flexible circuit board of claim 6, wherein the control chip is provided in the non-bending region.

8. The COF flexible circuit board of claim 6, wherein the control chip is provided in the bending region.

9. The COF flexible circuit board of claim 6, wherein the control chip is provided in the folding region.

10. A touch display panel, comprising a display panel and a touch screen, and further comprising a chip on film (COF) flexible circuit board, wherein the COF flexible circuit board comprises a flexible package substrate and a control chip packaged on the flexible package substrate, the flexible package substrate is connected with the display panel and the touch screen, the flexible package substrate is provided with an input terminal wiring and an output terminal wiring connected with the control chip, and the control chip comprises a display driver for controlling a display panel, a touch controller for implementing a touch control function, and a fingerprint identification controller for implementing fingerprint identification that are packaged together.

11. The touch display panel of claim 10, wherein the control chip further comprises a package layer packaging the display driver, the touch controller, and the fingerprint identification controller.

12. The touch display panel of claim 11, wherein the control chip is provided with a fingerprint sensor connected with the fingerprint identification controller, a holder for fixing the fingerprint sensor is provided on a surface of the package layer, the fingerprint sensor is fixed in the holder, and a fingerprint identification region is formed on a surface of the package layer.

13. The touch display panel of claim 11, wherein the control chip is provided with a fingerprint sensor connected with the fingerprint identification controller, the fingerprint sensor is embedded into the package layer, and a fingerprint identification region is formed on a surface of the package layer.

14. The touch display panel of claim 13, wherein the package layer comprises a circuit package region in which the display driver, the touch controller and the fingerprint identification controller are packaged, and an inlay region in which the fingerprint sensor is embedded.

15. The touch display panel of claim 10, wherein the flexible package substrate comprises a non-bending region, a bending region provided at one side of the non-bending region, and a folding region provided at one side of the bending region away from the non-bending region.

16. The touch display panel of claim 15, wherein the control chip is provided in the non-bending region.

17. The touch display panel of claim 15, wherein the control chip is provided in the bending region.

18. The touch display panel of claim 15, wherein the control chip is provided in the folding region.
